(19) United States
(12) Patent Application Publication
(10) Pub. No.: US 2020/0321240 A1
(43) Pub. Date: Oct. 8, 2020

(54) METHOD FOR FORMING A SHALLOW TRENCH STRUCTURE

(71) Applicant: Nanya Technology Corporation, New Taipei City (TW)

(72) Inventors: CHIHLIN HUANG, Taipei City (TW); YING CHENG CHUANG, Taoyuan City (TW)

(73) Assignee: Nanya Technology Corporation, New Taipei City (TW)

(21) Appl. No.: 16/375,264

(22) Filed: Apr. 4, 2019

(51) Int. Cl. H01L 21/762; H01L 21/311

(52) U.S. Cl. CPC H01L 21/762; H01L 21/31144; H01L 21/31116

(57) ABSTRACT

This invention provides a method for forming a shallow trench structure, including providing a substrate, forming a patterned photoresist layer on the substrate, performing an etching process with the patterned photoresist layer as a mask to form a shallow trench structure on the substrate, and applying plasma treatment unto the substrate with plasma produced from a mixture of CF₄ and O₂. Repeating the etching process and the plasma treatment until a shallow trench structure with a predetermined aspect ratio is obtained.

### BACKGROUND

### 1. Technical Field

This present invention relates to a method of forming a shallow trench, and in particular relates to a method of forming a shallow trench having a predetermined aspect ratio.

### 2. Description of Related Art

In the manufacturing process of a semiconductor device, in order to prevent the operation between active region elements such as a transistor and a transistor on the substrate from interfering with each other, it is necessary to isolate the transistors on each integrated circuit from other transistors to avoid short circuit phenomenon, a shallow trench isolation (STI) process is thus generated.

During the patterning etching process on the semiconductor substrate to form the shallow trench structure, the carbon of the patterned photoresist layer is converted into a polymer and combined with an etching gas and an etching process by-product to form a polymer residue. The polymer residues accumulate on the walls of the shallow trenches and even cause the etching process applied to the semiconductor substrate to stop. In the past, oxygen-containing plasmas have been used to remove these polymer residues, but these polymer residues cannot be completely removed from the wails of the shallow trenches, so that etching stop still occur.

### SUMMARY

The present invention therefore provides an improved shallow trench process to overcome the problems faced by the above shallow trench process.

According to an embodiment of the present disclosure, a shallow trench process of the present invention includes providing a substrate; forming a patterned photoresist layer on the substrate; performing an etching process with the patterned photoresist layer as a mask to form a shallow trench structure on the substrate; and performing a plasma treatment, wherein the plasma treatment is a plasma generated by a mixed gas of CF4 (carbon tetrafluoride) and O2 (oxygen) applied to the substrate having the shallow trench structure.

In an embodiment, the present invention further includes alternately repeating step of forming the shallow trench structure and the plasma treatment, until the shallow trench structure having a predetermined aspect ratio is formed on the substrate.

In an embodiment, the predetermined aspect ratio of the shallow trench structure is between 6:1 and 20:1.

In an embodiment, the volume ratio of CF₄ to O₂ in the mixed gas of CF₄ and O₂ is in a range from 1:3 to 1:30.

In an embodiment, the step of forming the shallow trench structure includes performing an anisotropic etching process. According to an embodiment of the invention, the anisotropic etching process includes a reactive-ion etching process.

In the above embodiments disclosed by the present invention, the plasma treatment of the plasma generated by a mixed gas of CF₄ (carbon tetrafluoride) and O₂ (oxygen) applied to the substrate having the shallow trench structure, can remove the polymer residues blockage in the shallow trench structure, and the shallow trench structure having a predetermined aspect ratio can be obtained.

These and other aspects and embodiments of the present invention will become readily apparent to those of ordinary skill in the field from the following detailed description and accompany drawings.

### BRIEF DESCRIPTION OF THE DRAWINGS

The size and dimension ratio of each part of the structures shown in figures does not limit the actual implementation of the invention.

FIG. 1 is a flow chart of a method for forming a shallow trench structure according to an embodiment of the present disclosure.

FIG. 2 to FIG. 7 show cross-sectional views of the semiconductor structure formed in each step of the method of forming a shallow trench structure of FIG. 1.

### DETAILED DESCRIPTION

The present invention provides a shallow trench process for use in a semiconductor process to form a shallow trench structure having a predetermined aspect ratio.

The embodiments will now be described in detail with reference to the accompany figures of the invention. In the accompany figures, the same and/or corresponding elements are denoted by the same reference numerals.

Various embodiments will be disclosed herein. However, it is to be understood that the disclosed embodiments are only used as an illustration that can be embodied in various forms. In addition, each of the examples given in connection with the various embodiments are intended to be illustrative but not limiting. Further, the figures are not necessarily conform to the sizes and dimension ratios of actual structures, and some features are magnified to show details of particular components (and any dimensions, materials, and similar details shown in the figures are intended to be illustrative and not limiting). Therefore, the particular structural and functional details are disclosed herein are not interpreted as limitations, but are used only to teach those skilled in the relevant field technicians to practice the basis of the disclosed embodiments.

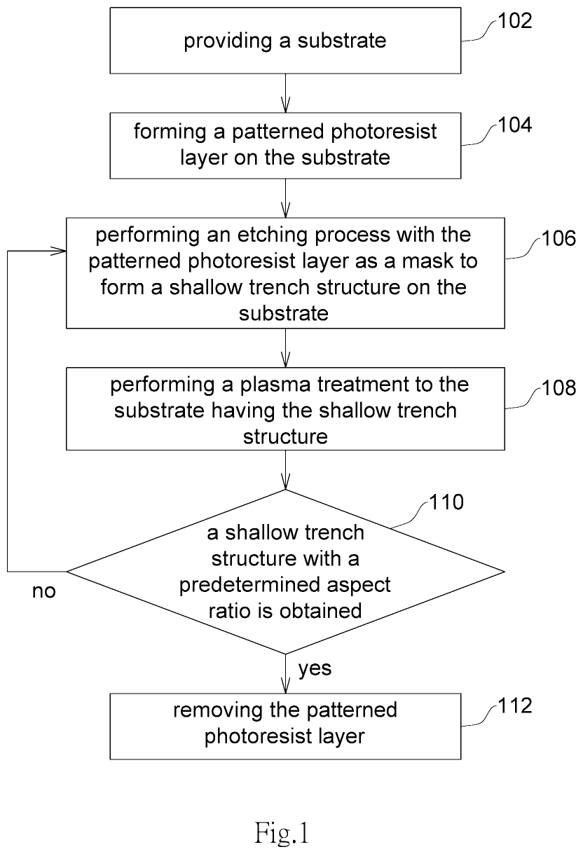

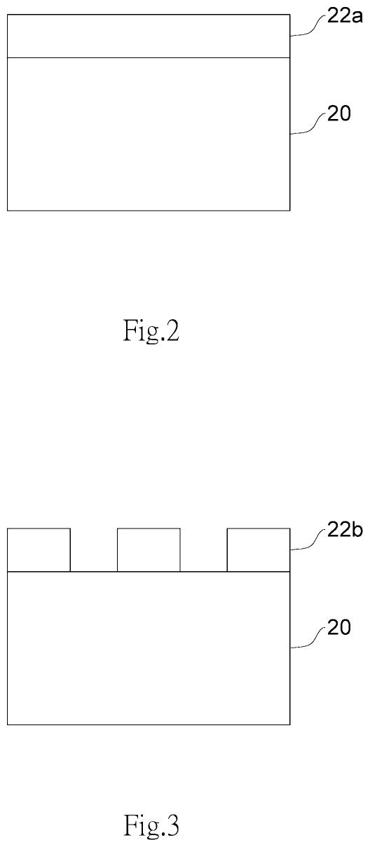

FIG. 1 is a flow chart of a method for forming a shallow trench structure according to an embodiment of the present invention. FIG. 2 to FIG. 7 show cross-sectional views of the semiconductor structure formed in each step of the method of forming a shallow trench structure of FIG. 1. First, at step 102, a substrate 20 such as a silicon substrate or other suitable semiconductor substrate is provided, and a photoresist layer 22a is formed on the substrate 20, as shown in FIG. 2. It should be noted that the substrate 20 may already have the basic components of the front-end process. In order to simplify the structures shown in the drawings, the basic components such as metal oxide semiconductor field effect transistors on the substrate 20 are omitted from the drawings for clarity.

Next, at step 104, a patterned photoresist layer 22b is formed on the substrate 20 by a lithography technique, as shown in FIG. 3.

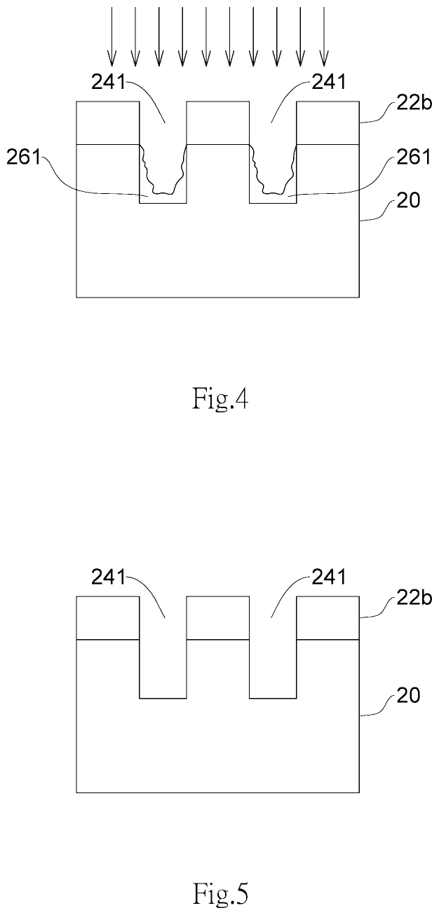

Next, at step 106, the patterned photoresist layer 22b is used as a mask to perform drying etching, for example, anisotropic etching, to form a plurality of shallow trench structures 241 on the substrate 20. In an embodiment of the invention, the anisotropic etching can be performed by a reactive-ion etching (RIE) process. During, the shallow trench etching process of step 106, carbons of the patterned photoresist layer 22b are converted into polymers and combined with the etching gas and the etching process by-product to form polymer residues 261, and these polymer residues 261 are deposited on the wall surfaces of the shallow trench structures 241 as shown in FIG. 4.

Next, at step 108. the substrate 20 having the shallow trench structures 241 is subjected to a plasma treatment. The plasma treatment is to apply a plasma generated by a mixed gas of CF₄ (carbon tetrafluoride) and O₂ (oxygen) to the substrate 20 having the shallow trench structures 241 to remove the polymer residues 261 deposited on the shallow trench wall surfaces as shown in FIG. 5. In one embodiment of the present invention, the volume ratio of CF₄to O₂ in the mixed gas of CF₄ and O₂ is in a range from 1:3 to 1:30. After the plasma treatment of the substrate 20 is performed in step 108, if the shallow trench structure 241 on the substrate 20 has a predetermined aspect ratio (step 110), then step 112 is performed to remove the patterned photoresist layer 22b from the substrate 20. If the shallow trench structures 241 do not reach the predetermined aspect ratio, then return to step 106 to continue the shallow trench etching process.

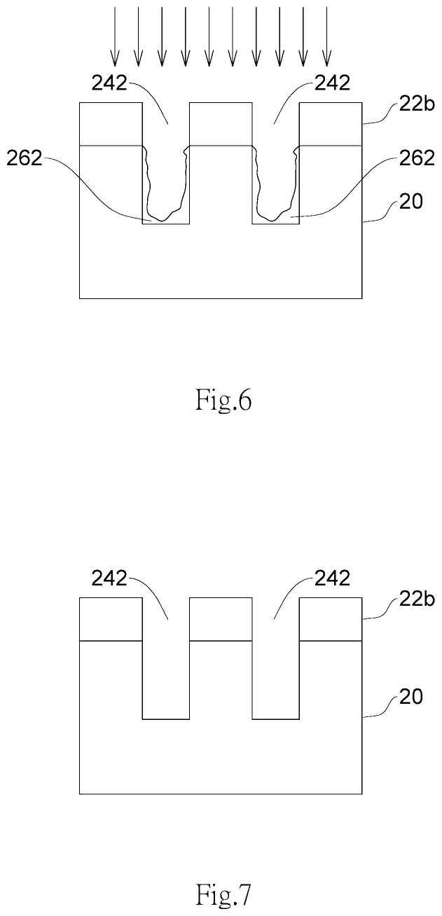

Referring to FIG. 6, during the step 106, the shallow trench structures 242 are formed on the substrate 20, and carbons of the patterned photoresist layer 22b are converted into polymers and combined with an etching gas and an etching process by-product to form polymer residues 262, and these polymer residue 262 are deposited on the wall surfaces of the shallow trench structures 242. Therefore, the plasma treatment of the step 108 is performed on the substrate 20 to remove the polymer residues 262 deposited on the shallow trench wall surfaces as shown in FIG. 7. As such, the present invention obtains a shallow trench structure having a predetermined aspect ratio (step 110) by alternately repeating steps 106 and 108. When a shallow trench structure having a predetermined aspect ratio is obtained, step 112 is performed to remove the patterned photoresist layer 22b from the substrate 20. In an embodiment of the invention, the shallow trench structure has an aspect ratio of 6:1 moreover, it may have an aspect ratio of 10:1 and moreover, it may have an aspect ratio of 20:1.

In an embodiment, the shallow trench structure may be a shallow trench structure with vertical sidewalls or with non-vertical sidewalls. However, the above embodiments are not intended to limit the disclosure.

Although the method of fabricating the shallow trench of the present invention has been described in terms of one or more embodiments, it is to be understood that the present disclosure is not limited to the disclosed embodiments. The present invention encompasses various modifications and similar arrangements in the spirit and scope of the claims, and the broadest interpretation should be given to cover all modifications and similar structures. The disclosure of the present invention also encompasses any of the embodiments of the following claims.

1. A method for forming a shallow trench structure, comprising:
providing a substrate;
forming a patterned photoresist layer on the substrate;
performing an etching process with the patterned photoresist layer as a mask to form a shallow trench structure on the substrate; and
performing a plasma treatment, wherein the plasma treatment is a plasma generated by a mixed gas of CF₄ (carbon tetrafluoride) and O₂ (oxygen) with a volume ratio of CF₄ to O₂ in a range from 1:3 to 1:30 applied to the substrate having the shallow trench structure.

2. The method as claimed in claim 1, further comprising alternately repeating the steps of forming the shallow trench structure and the plasma treatment, until the shallow trench structure having a predetermined aspect ratio is formed on the substrate.

3. The method as claimed in claim 2, wherein the predetermined aspect ratio of the shallow trench structure is between 6:1 and 20:1.

4. (canceled)

5. The method as claimed in claim 1, wherein the step of forming the shallow trench structure includes performing an anisotropic etching process.

6. The method as claimed in claim 5, wherein the anisotropic etching process includes a reactive-ion etching process.

7. The method as claimed in claim 1, wherein the substrate includes a silicon substrate.

8. The method as claimed in claim 2, further comprising removing the patterned photoresist layer.
